(19) United States
(12) Patent Application Publication
(10) Pub. No.: US 2026/0198048 A1
(43) Pub. Date: Jul. 9, 2026

(54) Semiconductor-Dielectric Interfaces

(71) Applicant: Zinite Corporation, Edmonton (CA)

(72) Inventors: Douglas Barlage, Edmonton (CA); Ken Cadien, Edmonton (CA); Fenglin Liu, Edmonton (CA); Eric Milburn, Edmonton (CA); Lian C.T. Shoute, Edmonton (CA)

(73) Assignee: Zinite Corporation, Edmonton (CA)

(21) Appl. No.: 19/426,873

(22) Filed: Dec. 19, 2025

Related U.S. Application Data
(60) Provisional application No. 63/742,271, filed on Jan. 6, 2025.

(51) Int. Cl. H10D 30/67; H10D 30/01

(52) U.S. Cl. CPC H10D 30/6757; H10D 30/031; H10D 30/6755

(57) ABSTRACT

A example thin-film transistor a source disposed on a substrate, a drain disposed on the substrate, a body of channel material disposed between the source and the drain, a body of gate material that extends over the body of the channel material, a body of dielectric material that is disposed between the body of gate material and the body of channel material and that extends over the body of channel material, and an interceding material disposed between the body of channel material and the body of dielectric material. The body of channel material includes a metal oxide and is operable to form a carrier channel between the source and the drain. The interceding material is operable to reduce or eliminate an influence of a crystal structure of the body of channel material on a structure of the body of dielectric material.

### FIELD

The present disclosure relates to thin-film transistors and methods of making same.

### BACKGROUND

The manufacture and operation of thin-film transistors (TFTs) are heavily dependent on the materials selected.

### SUMMARY

According to an aspect of the present disclosure, a thin-film transistor includes a substrate, a source disposed over a portion of the substrate, a drain disposed over a portion of the substrate, a body of channel material disposed over at least a portion of the substrate that extends between the source and the drain, a body of gate material that extends over the body of the channel material, a body of dielectric material that is disposed between the body of gate material and the body of channel material and that extends over the body of channel material, and an interceding material disposed between the body of channel material and the body of dielectric material. The body of channel material includes a metal oxide, the body of channel material being operable to form a carrier channel between the source and the drain when sufficient voltage is applied to the body of gate material. The interceding material is operable to reduce or eliminate an influence of a crystal structure of the body of channel material on a structure of the body of dielectric material.

The interceding material may include one or more of silicon dioxide, silicon oxynitride, and silicon nitride.

The interceding material may be amorphous.

The interceding material may have a graduated composition of two or more of silicon dioxide, silicon oxynitride, and silicon nitride.

The channel material may be tin oxide and the dielectric material may be hafnium oxide.

The tin oxide channel material may have a preferred crystallite orientation of Miller index <110>.

The hafnium oxide dielectric material may have a preferred crystallite orientation of Miller index <−111>. The hafnium oxide dielectric material may have a preferred crystallite orientation of Miller index <020>. The hafnium oxide dielectric material may have an amorphous structure.

The interceding material may be formed as a discrete layer.

The interceding material may be blended with the channel material.

The interceding material may be graduated according to a gradient with respect to the channel material such that the proportion of interceding material relative to channel material increases with increasing distance from the body of channel material.

According to an aspect of the present disclosure, a method of forming a thin-film transistor includes forming a source over a substrate, forming a drain over the substrate, forming a body of channel material between the source and the drain, forming an interceding material at the body of channel material, and forming a body of dielectric material over at least a portion of the interceding material. The interceding material reduces or eliminates an influence of a crystal structure of the body of channel material on a structure of the body of dielectric material.

The interceding material may include one or more of silicon dioxide, silicon oxynitride, and silicon nitride.

The interceding material may be amorphous.

The method may further include forming the interceding material with a graduated composition of two or more of silicon dioxide, silicon oxynitride, and silicon nitride.

The channel material may be tin oxide and the dielectric material may be hafnium oxide.

The tin oxide channel material may have a preferred crystallite orientation of Miller index <110>.

The hafnium oxide dielectric material may have a preferred crystallite orientation of Miller index <−111>. The hafnium oxide dielectric material may have a preferred crystallite orientation of Miller index <020>. The hafnium oxide dielectric material may have an amorphous structure.

The method may further include forming the interceding material as a discrete layer on the body of channel material.

The method may further include blending the interceding material with the channel material.

The method may further include forming the interceding material as graduated according to a gradient such that a proportion of interceding material relative to the channel material increases with increasing distance from the body of channel material.

The method may further include forming the interceding material with a proportion with respect to the channel material using thickness modulation of a layer of the interceding material and/or a layer of the channel material.

The method may further include forming the interceding material with a proportion with respect to the channel material using frequency modulation of layers of the interceding material and the channel material.

The method may further include forming the interceding material with a proportion with respect to the channel material in an atomic layer of the interceding material and the channel material.

The method may further include forming the body of channel material, the interceding material, and the body of dielectric material using atomic layer deposition.

### BRIEF DESCRIPTION OF THE FIGURES

FIG. 1 is a cross-sectional view of an example thin-film transistor with an interceding material between channel and gate dielectric materials according to some examples.

FIG. 2 is a cross-sectional diagram of an example process of forming a layer of channel material, a layer of dielectric material, and an interceding material.

FIG. 3A is a cross-sectional diagram of an example process of forming a layer of channel material with interceding material and a layer of dielectric material.

FIG. 3B is a cross-sectional diagram of another example process of forming a layer of channel material with interceding material and a layer of dielectric material.

FIG. 4 is a plot of a stepwise gradient from channel material to interceding material.

FIG. 5 is a diagram of an example process of forming interceding material using steric hinderance.

FIG. 6 is a plot of example energy band alignment among a hafnium oxide dielectric, tin oxide channel, and silicon dioxide interceding material.

FIG. 7 is a plot of example energy band alignment among a hafnium oxide dielectric, tin oxide channel, and graduated silicon dioxide interceding material.

FIG. 8 is a flowchart of an example method of forming a thin-film transistor with an interceding material between channel and gate dielectric materials.

### DETAILED DESCRIPTION

An interceding interface between a semiconductor material and a dielectric material in a thin-film transistor is disclosed. When layers of material are successively formed in stacks or other arrangements, the crystal structure of a given body of material may influence the structure of an adjacent body of material. In some cases, this influence causes a previously formed material with a particular crystal structure to “seed” the crystal structure of another material being formed over the previously formed material. In various cases, influence as used herein may be considered to be the tendency for atoms in a crystal undergoing formation to arrange themselves according to an underlying crystal structure on which the atoms are deposited. The arrangement of atoms of one material may change in response to the material contacting another material having a different arrangement of atoms. Stimuli, such as temperature, may affect this phenomenon. When this influence of one crystal structure on another is undesirable, an interceding material may be provided between the two bodies of material to reduce or eliminate the influence of one on the other. For example, an amorphous interceding material may be formed over a previously formed material to provide a neutral substrate for the growth of the next material. This may be useful to obtain and/or preserve the desired structures of adjacent materials.

In addition, interceding material may be provided to increase the energy needed for electrons (or carriers in general) to pass from one material to another. An interceding material with a suitably high conduction band minimum may provide a barrier to undesirable electron (carrier) transfer.

Still further, interceding material may also provide a barrier against migration of chemical species, such as oxygen, where such migration can detrimentally affect operation of the thin-film transistor.

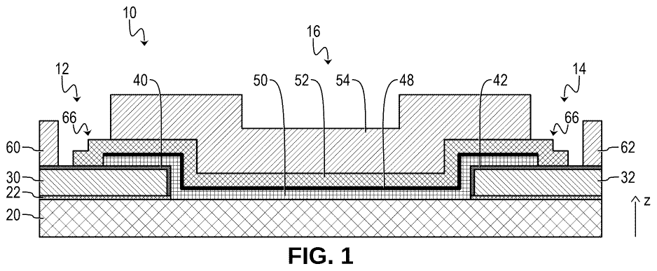

FIG. 1 shows an example TFT 10 according to some examples. The TFT 10 includes a source 12, drain 14, and gate 16. In various examples, the TFT 10 may be manufactured using back end of line (BEOL) and/or middle of line (MOL) processes.

The TFT 10 is formed with a planar substrate 20. The substrate 20 may be disposed over another layer of TFTs, whether manufactured in accordance with techniques described in the present disclosure or by another technique. For example, the substrate 20 may be disposed over a layer of complementary metal-oxide-semiconductor (CMOS) devices or other front end of line (FEOL) devices.

Examples of materials for the substrate 20 include silicon dioxide; silicon nitride; glass; fluorosilicate glass (FSG); a silicon wafer whose surface is processed with wet thermal oxide (WTO) or similar treatment; carbon doped oxide (CDO); organic polymers such as perfluorocyclobutane or polytetrafluoroethylene; organosilicates such as silsesquioxane, siloxane, organosilicate glass; flexible polymer; plastic; etc. Suitable combinations of such materials may also be used.

An adhesion layer 22 may be formed over the substrate 20 to promote adhesion of material to the substrate 20. The adhesion layer 22 may be formed of titanium nitride, hafnium nitride, or similar material.

The source 12 is formed of a body of source material 30 disposed on the substrate 20. In this example, the body of source material 30 is formed by sputtering to a thickness of about 25 nm. In other examples, other source thicknesses may be used, such as about 30 nm, 20 nm, 15 nm, 10 nm, etc.

Examples of source materials include various metals and other conductors, such as nickel, ruthenium, tungsten, cobalt, molybdenum, copper, titanium nitride, etc. Further examples of source materials include heavily doped n-type materials, degenerate n-type silicon, and III-V compound semiconductors with high conductivity with predominately n-type or electron transport, etc. Suitable combinations of such materials may be used. Ruthenium is presently preferred for the source material.

In this example, the drain 14 is formed of a body of drain material 32 and has the same or similar material and/or structure as the source 12. Accordingly, such material and/or structure may be referred to as “source/drain” or similar terminology. In other examples, the drain 14 has a material and/or structure different to the source 12.

The adhesion layer 22 promotes the adhesion of the bodies of source and drain material 30, 32 to the substrate 20. In other examples, the adhesion layer 22 may be omitted if the source/drain material has suitable adhesion without it.

The body of source material 30 may be subject to inline treatment, such as plasma treatment, anneal treatment, material deposition, chemical or electro-chemical treatment, or similar. Different types of treatment may be combined. A treatment may be repeated two or more times.

The treatment forms a source-channel interface 40 at the body of source material 30 at least between the body of source material 30 and semiconductor channel material 50. When an n-type channel material is used, the source-channel interface 40 may be p-type or may behave in a p-type manner. When a p-type channel material is used, the source-channel interface 40 may be n-type or may behave in an n-type manner. The source-channel interface 40 may tune the threshold voltage at which the TFT 10 turns on, making the transistor operate in enhancement or depletion mode, to reduce leakage current through TFT 10 in the off state. The source-channel interface 40 may create a repository of complimentary excess positive or negative charge that functions to deplete the channel in at least the region of the body of channel material 50 adjacent the body of source material 30. In this manner, the source-channel interface 40 serves as a voltage-controlled electron transport barrier, resulting in substantially less current flow through body of channel material 50 when the TFT 10 is in an off state. Further, the source-channel interface 40 may also serve to reduce stress induced leakage currents (“SILC”) in TFT 10 by inhibiting the formation of interlayer stress-induced flaws between the body of channel material 50 and the body of source material 30. A drain-channel interface 42 may be similarly formed and may have similar characteristics, but it is contemplated that the source-channel interface 40 provides significant benefit without the drain-channel interface 42 and may provide most or all of the benefit.

In this example, the bodies of source and drain material 30, 32 are treated with oxygen plasma to form a layer of oxidized material that are the source and drain channel interfaces 40, 42. In the example of ruthenium as source/drain material, the source and drain channel interfaces 40, 42 are consequently formed of ruthenium oxide, which is contemplated to be primarily or exclusively of the +4 oxidation state, i.e., RuO₂.

For further detail concerning the source and drain channel interfaces 40, 42 and other aspects of the TFT 10, reference may be made to U.S. Pat. No. 11,949,019, which is incorporated herein by reference in its entirety.

The TFT 10 further includes a body of semiconductor channel material 50 disposed between the source 12 and drain 14. In this example, the body of channel material 50 is disposed partially over the bodies of source and drain material 30, 32 and over the substrate 20 between the bodies of source and drain material 30, 32. The body of channel material 50 is a metal oxide. In this example, the body of channel material 50 is a layer of tin oxide, which is primarily or entirely tin (IV) oxide (SnO₂), with a thickness of about 5 nm to about 10 nm. In this example, the layer of tin oxide is about 7 nm thick.

The tin oxide forming the body of channel material 50 is generally polycrystalline with a preferred crystallite orientation of Miller index <110>, as determined using grazing-incidence x-ray diffraction (GI-XRD) with ω=0.5° on 20 nm and/or 40 nm thick samples. Polycrystalline tin oxide with this preferred crystal orientation provides good carrier mobility and good stability, which improves the performance and useful life of the TFT 10.

For sake of clarity, tin oxide with an orientation of <110> means that one of the directions in the family of directions <110>, such as direction, is substantially normal to the plane of the substrate 20. In other words, a plane of the family {110}, such as the plane (110), is substantially parallel to the plane of the substrate 20.

The crystallinity of the thin film of tin oxide is preferably at least about 80%, more preferably at least about 85%, more preferably at least about 90%, and still more preferably at least about 95%. Regions outside the 2θ angular range of 20°-60° may be ignored when computing crystallinity.

It is important to note that GI-XRD measurements may be performed on thicker samples of tin oxide (e.g., 20 nm or 40 nm) to provide sufficient accuracy, as the GI-XRD technique is known to lose accuracy as film thickness decreases. While 20 nm and 40 nm are considerably thicker than the body of channel material 50 (about 5-10 nm, e.g., 7 nm) discussed above, GI-XRD may still be used to establish useful process parameters. Forming process parameters may be established by having a thicker film, such as 20 nm or 40 nm, take the preferred crystal orientation. A thinner film, such as 7 nm, may then be deposited using these established process parameters. If the thinner film performs sufficiently well as a semiconductor in an implementation of a transistor, then the process parameters are useful. While it is contemplated that the thinner film will have the same or similar crystal orientation as the thicker film, this need not be confirmed with measurement.

The TFT 10 further includes an interceding material 48 disposed over at least a portion of the body of channel material 50. The interceding material 48 serves to interrupt the crystal structure of the body of channel material 50, so that the influence of the crystal structure of the body of channel material 50 on the desired structure of the subsequently formed body of gate dielectric material 52, whether crystalline or amorphous, is reduced or eliminated. In this example, the interceding material 48 is composed of silicon dioxide (SiO₂) that is primarily or exclusively amorphous. In other examples, other materials, such as silicon oxynitride (SiOₓN_{y}) or silicon nitride (Si₃N₄), may be used for the interceding material 48. In still other examples, combinations of two of more of silicon dioxide, silicon oxynitride, and silicon nitride may be used the interceding material 48.

The thickness of the interceding material 48 should be sufficient to disrupt the influence of the channel material (i.e., tin oxide) on the dielectric material (i.e., hafnium oxide) that will be subsequently formed over the channel material. It is contemplated that several or even one layer of silicon dioxide molecules may be sufficient, depending on other factors, such as forming technique and forming parameters. Using more silicon dioxide than strictly necessary to reduce or eliminate the influence of the crystal structure of the body of channel material 50 on the crystal/amorphous structure of the body of gate dielectric material 52 may be useful for robustness. Hence, the thickness of the interceding material 48 may range from one or several molecular layers to about 2 nm. In various examples, the interceding material 48 has a nominal thickness of 0.5 nm.

The TFT 10 further includes a body of dielectric material 52 disposed over the interceding material 48, which provides a neutral substrate for growth of hafnium oxide dielectric material 52. In various examples, the body of dielectric material 52 may have various properties.

In some examples, the body of gate dielectric material 52 is a layer of polycrystalline hafnium oxide that is primarily or entirely hafnium (IV) oxide (HfO₂) with a preferred crystallite orientation of Miller index <−111> (also written as <111>), as determined using grazing-incidence x-ray diffraction (GI-XRD) with ω=0.5° on 20 nm and/or 40 nm thick samples. Polycrystalline hafnium oxide with this preferred crystal orientation provides sufficient stability, which improves the performance and useful life of the TFT 10. While other crystallite orientations, such as <020>, <100>, <200>, and <111>, may be present, it is preferred that the body of dielectric material 52 has a dominant crystallite orientation of <−111>.

In other examples, the body of gate dielectric material 52 is a layer of

polycrystalline hafnium oxide that is primarily or entirely hafnium (IV) oxide (HfO₂) with a preferred crystallite orientation of Miller index <020>. The secondary preferred orientation may be <−111>.

In still other examples, the body of gate dielectric material 52 is a layer of polycrystalline hafnium oxide that is primarily or entirely hafnium (IV) oxide (HfO₂) with preferred crystallite orientations of Miller index <−111> and <020>, which are present in approximately equal quantities.

In various crystalline examples, the crystallinity of the thin film of hafnium oxide as-deposited is at least about 60% and may increase to about 90%, 95%, or more after forming gas anneal (e.g., 120 minutes at 400° C.). In other examples, the thin film of hafnium oxide may have lower crystallinity or may be amorphous.

In still other examples, the body of gate dielectric material 52 has mainly or entirely amorphous structure.

The body of gate dielectric material 52 has a suitable thickness, such as about 7-15 nm thick, for example, about 12.5 nm.

GI-XRD and other aspects discussed above related to tin oxide also apply to hafnium oxide.

The TFT 10 further includes a body of gate material 54 (also termed “gate metal”) disposed over the gate dielectric material 52. The gate material is a conductor. Examples of gate materials include tungsten, titanium, titanium nitride, molybdenum, gold, platinum, aluminum, nickel, copper, chromium, hafnium, indium, manganese, iron, vanadium, zinc, tantalum, or alloys/combinations thereof. In this example, the body of gate material 54 is a layer of tungsten about 20-40 nm thick, such as about 30 nm thick.

The TFT 10 further includes a source electrode 60 as part of the source 12 and a drain electrode 62 as part of the drain 14. The source electrode 60 is in electrical contact with the body of source material 30 to conduct current to/from the body of source material 30. Likewise, the drain electrode 62 is in electrical contact with the body of drain material 32 to conduct current to/from the body of drain material 32. Examples of materials for electrodes 60, 62 include the gate materials listed above.

In operation, when a voltage is applied across the source electrode 60 and a drain electrode 62, and when a suitable voltage is applied to the body of gate material 54, a carrier channel forms in the body of channel material 50, which causes flow of current from source 12 to drain 14. When the voltage is removed, the flow of off-current (often called leakage current) is reduced to a very low amount, assisted by the source-channel interface 40 and, optionally, the drain-channel interface 42.

TFT 10 may be manufactured using FEOL processes, MOL processes, BEOL processes, or a combination of such. A manufacturing process may include forming one or more layers of TFTs 10 over other devices made using FEOL, MOL, and/or BEOL processes.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present invention.

During manufacture, the TFT 10 in its partially or fully complete state may be subject to an anneal, such as a forming gas (i.e., nitrogen and hydrogen) anneal, as may be required for various reasons, such as to stabilize material or to support the forming of material of the TFT 10 or other materials, components, or devices that are formed before or after the TFT 10 is formed. For example, the forming of interlayer dielectric (ILD) may involve forming gas anneal, the use of silane (SiH₄) may introduce hydrogen, etc.

Any suitable number and configuration of forming gas anneals may be performed. Annealing may be done at about 400° C. for about 120 minutes, for example, or longer (e.g., 3 or 4 hours). Higher temperatures and longer times may also be useful.

A substrate 20 may be formed as discussed above. An adhesion layer 22 of, for example, titanium nitride may be formed over the substrate by PEALD, for example.

A layer of source/drain material, e.g., ruthenium, is formed over the adhesion layer 22. The source/drain material may be formed by sputtering to a desired thickness.

The layer of source/drain material is then patterned to form separate bodies of source and drain material 30, 32 and define a gap therebetween. Lithography and etching, such as inductively coupled plasma reactive ion etching (ICP-RIE), may be used to form the bodies of source and drain material 30, 32. The adhesion layer 22, if used, should also be etched to avoid shorting the source 12 and drain 14.

Next, the source and drain channel interfaces 40, 42 are formed. This includes treating the bodies of source and drain material 30, 32 with oxygen plasma, or similar treatment, to form a layer of oxidized material. In various examples, a sequence of plasma treatments is used as follows: nitrogen/hydrogen plasma for a duration of about 30 seconds; then oxygen plasma for a duration of about 60 seconds; and then nitrogen plasma for a duration of about 180 seconds. This sequence may be repeated two or more times. As discussed above, when ruthenium is used as the source/drain material, the resulting source and drain channel interfaces 40, 42 include ruthenium oxide.

Subsequently, a layer of channel material 50 is formed over the bodies of source and drain material 30, 32 and over the substrate 20 within the gap between the bodies of source and drain material 30, 32.

The layer of channel material 50, i.e., tin oxide, may be formed by PEALD with oxygen plasma, T-ALD, or similar technique. Tetraallyltin may be used as the precursor. In various examples, chlorine, fluorine, nitrogen, or other chemical species may be introduced during the deposition process, so that the layer of channel material 50 includes such species.

Annealing may be useful to develop and/or maintain the preferred crystallite orientation of the tin oxide discussed above. Annealing may be performed immediately after deposition of the layer of channel material 50 or at a later stage. Example anneal conditions are 400° C. for 120 minutes.

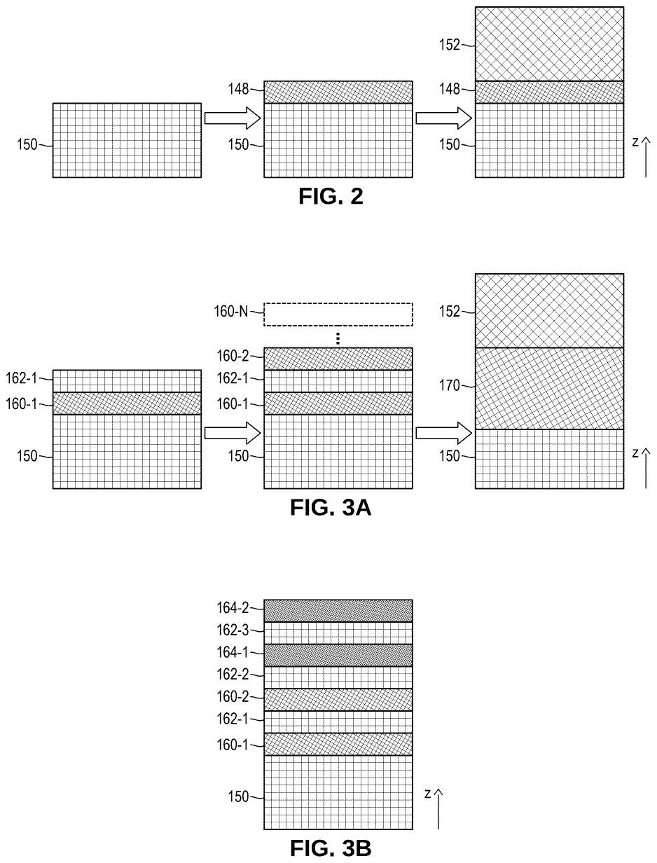

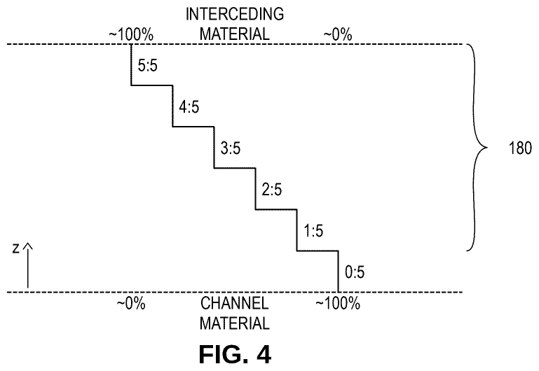

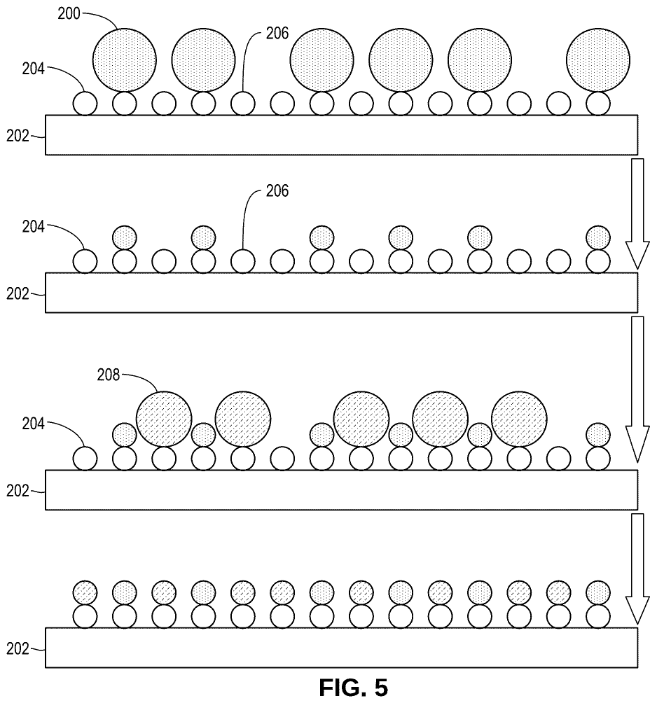

After or during formation of the body of channel material, interceding material 48 is formed at the body of channel material 50 to provide a neutral basis for subsequent formation of the body of dielectric material 52. Interceding material 48 may be formed in various ways. Interceding material 48 may be formed as a discrete layer on the completed body of channel material 50 (FIG. 2). Alternatively, interceding material 48 may be formed with alternating layers between layers of channel material (FIGS. 3A, 3B, and 4). Further, steric hindering may be used to facilitate the forming of interceding material 48 by ALD (FIG. 5).

As shown in FIG. 2, interceding material 148 may be formed as a discrete layer on a completed layer of channel material 150. After channel material 150 is formed, such as by ALD, a layer of interceding material 148 is formed, for example by ALD, on the layer of channel material 150. Then, a layer of gate dielectric material 152 is formed over the layer of interceding material 148.

As shown in FIG. 3A, alternating layers comprising an interceding layer 160-1, 160-2 (generally referred to as 160) and a layer of channel material 162-1 (generally referred to as 162) may be formed, for example by ALD, over a base layer of channel material 150, though which current flows in the completed TFT. More specifically, a first interceding layer 160-1 is formed on the main layer of channel material 150. Then, a layer of channel material 162-1 is formed on the first interceding layer 160-1. A second interceding layer 160-2 is then formed on the layer of channel material 162-1. This alternating pattern may be repeated for N layers of interceding material and channel material (i.e., layers 162-2, 160-3, etc.).

Then, the formed structure may be annealed (e.g., at 400° C. for 120 minutes) to mix the interceding layer 160-1, 160-2 and channel material 162 into a blend of interceding and channel materials 170. In many cases, layers of interceding material 160, layers of channel material layer 162 sandwiched between layers of interceding material 160, and a portion of the base layer of channel material 150 on which a first interceding material layer 160-1 is formed are subsumed into the blend during the annealing process. A layer of gate dielectric material 152 is then formed over the blended interceding material 170.

The alternating layers of material 160, 162 may be thin, such as from about one or several molecules to about 1 nm, so as to suitably integrate the materials 160, 162. Multiple layers of channel material 162 and interceding material layers 160-1, 160-2 . . . 160-N may be formed according to a material layer composition. A gradient from exclusively channel material 162 to exclusively interceding material 160 may be provided, if desired, by progressively increasing the thickness of layers of interceding material 160 relative to the thickness of the layers of channel material 162. For example, layers of interceding material 160 may be thickened while layers channel material 162 are thinned or held to constant thickness. Alternatively, layers of interceding material 160 may be thickened or held to constant thickness while layers channel material 162 are thinned. This methodology may be referred to as thickness modulation. In another methodology, which may be termed frequency modulation, layer thickness is held constant (but not necessarily equal between interceding material and channel material) and the relative frequency of layers of interceding material 160 and channel material 162 is controlled. In still another example, thickness modulation and frequency modulation are combined.

FIG. 4 shows an example of a stepwise gradient from channel material to interceding material. Each step represents a different proportion of interceding material relative to channel material. For example, an initial step may provide 1 dose of interceding material for every 5 doses of channel material (1:5 interceding material to total), while a subsequent step may increase the proportion of interceding material to 2 doses for every 3 doses of channel material (2:5 interceding material to total), and so on, until only interceding material is deposited. Doses may be implemented by ALD cycles or similar metering of material, and each step may define multiple ALD cycles of channel material and/or interceding material. The example numbers provided are merely illustrative. A progressive pattern of increasing interceding material and decreasing channel material may be linear, as per the example depicted, or non-linear. In various examples, the deposition of material is graduated from 100% channel material and 0% interceding material to 0% channel material and 100% interceding material. A graduated layer of interceding material 180 may thus be formed.

A graduated transition from channel material to interceding material may reduce stress and increase stability of the proximate channel material.

The same principle may be applied to the transition from interceding material to gate dielectric material. A graduated transition, whether of linear or non-linear curvature, may be used.

As mentioned above, interceding material may include a combination of materials, such as silicon dioxide, silicon oxynitride, and/or silicon nitride. In various examples, the composition of the interceding material follows a gradient. For example, the interceding material may be silicon dioxide or silicon oxynitride adjacent the channel material and the interceding material may transition to silicon nitride towards the gate dielectric material. In one example, a gradient of interceding material transitions from a starting composition, such as silicon dioxide, adjacent the channel material to an ending composition, such as silicon nitride. In another example, the starting composition is silicon oxynitride and the ending composition is silicon nitride.

In addition, a gradient in the composition of interceding material may be combined with a gradient of interceding material with respect to channel material, as shown in FIG. 4. That is, the composition of the interceding material may change as the proportion of interceding material to channel material increases.

FIG. 3B shows an example of interleaved layers of different interceding materials 160, 164 and channel material 162. Near the base layer of channel material 150, layers of first interceding material 160-1, 160-2 (e.g., silicon dioxide) are interleaved with layers of channel material 162-1, 162-2. Further from the base layer of channel material 150, layers of second interceding material 164-1, 164-2 (e.g., silicon nitride) are interleaved with layers of channel material 162-2, 162-3.

Steric hinderance may be used to facilitate the forming of interceding material 48 by ALD. A precursor molecule used to deposit an atomic layer of material may be quite large and may thus block nearby reaction sites as it undergoes physisorption with the substrate. This may result in at least some reaction sites going unused during an ALD cycle, which may cause precursor to be wasted and/or may cause flaws in the layer formed. It is known to mitigate this by using multiple pulses of the precursor (AₓBAₓB . . . pulsed atomic layer deposition: Numerical growth model and experiments; Muneshwar et al. ; 2015). This technique may be modified to deposit a single layer that includes both channel material and interceding material according to the present invention.

FIG. 5 is a diagram of an example process of forming interceding material through blending using steric hinderance. As shown schematically in FIG. 5, a precursor 200 for tin oxide channel material is introduced to a substrate 202 during ALD. (Note that molecules are represented by circles for sake of simplicity.) The precursor 200 is physiosorbed with respect to reaction sites 204 and, due to the size of the precursor molecule, it sterically hinders other reaction sites 206. Once the precursor is chemisorbed, previously sterically hindered reaction sites 206 may become available. At this time, a precursor 208 for silicon dioxide interceding material may be introduced to utilize these reaction sites 206. Accordingly, a single layer of deposited material may be formed of two different molecules, i.e., tin oxide and silicon dioxide. The relative proportions of tin oxide and silicon dioxide in a given atomic layer may be controlled by modulating pulses of precursor materials. For example, more pulses of the precursor for tin oxide channel material will result in fewer sterically hindered reaction sites and thus less opportunity for silicon dioxide interceding material to be formed in the same layer. Conversely, fewer pulses of the precursor for tin oxide channel material will result in more sterically hindered reaction sites and thus more opportunity for silicon dioxide interceding material to be formed in the same layer. Thus, by using suitable precursors and taking advantage of steric hinderance, a single mixed layer of tin oxide and silicon dioxide may be formed and, further, a stack of layers with graduated proportions of tin oxide and silicon dioxide may be formed.

Accordingly, in addition to thickness and frequency modulation of layers, intralayer modulation of species may be used to graduate the tin oxide channel material to the silicon dioxide interceding material. In various implementations, any one or combination of thickness modulation, frequency modulation, and intralayer modulation of species may be used.

After the interceding material 48 is formed, a body of gate dielectric material 52 is formed. This may be done in two separate deposition and patterning operations. After an initial deposition of dielectric material, the dielectric material and underlying interceding material and channel material may be patterned together using the same mask. Then, to prevent the channel material from shorting to the body of gate material 54, a second layer of dielectric material may be deposited and patterned in a manner that encapsulates the channel material, as shown at 66 in FIG. 1. Alternatively, a single deposition and patterning operation may be used to form the dielectric material.

The initial layer of dielectric material is formed over the layer of channel material. A layer of hafnium oxide may be formed by PEALD with oxygen plasma, T-ALD, or similar technique. The initial layer of hafnium oxide may be deposited to a desired thickness, such as about 5 nm. When hafnium oxide is formed using PEALD, the precursor tetrakis(dimethylamino)hafnium (TDMAH) may be used with oxygen plasma.

The layers of tin oxide and hafnium oxide are then patterned. Lithography and etching, such as ICP-RIE, may be used. The same mask may be used to give the same pattern to both layers. This patterning completes the body of channel material 50.

The second layer of gate dielectric material is then formed over the patterned initial layer of dielectric material. PEALD, T-ALD, etc. may be used, as discussed above. The second layer of hafnium oxide may be deposited to a desired thickness, such as about 7.5 nm.

The second layer of gate dielectric material is then patterned. Lithography and etching, such as ICP-RIE, may be used. The pattern used to form the second layer of dielectric material should be larger than the pattern used to form the initial layer of dielectric material and channel material, so that edges of the body of channel material 50 are covered by dielectric material, as shown at 66 in FIG. 1. This patterning completes the body of dielectric material 52.

Annealing may be useful to develop and/or maintain the preferred structure of the hafnium oxide. Annealing may be performed immediately after deposition of the complete body of dielectric material 52, after one or both of two separate deposition and patterning operations, or at a later stage. Example anneal conditions are 400° C. for 120 minutes.

Subsequently, a layer of gate material is formed. In this example, the layer of gate material ultimately forms the body of gate material 54 and the source and drain electrodes 60, 62. The layer of gate material may be formed by sputtering material mentioned above.

The layer of gate material may then be patterned to form the separate body of gate material 54 and source and drain electrodes 60, 62. Lithography and etching, such as ICP-RIE, may be used.

Thus, a transistor 10 of the structure shown in FIG. 1 is formed.

Further forming may be performed, such as annealing, as may be required for the particular application of the TFT 10.

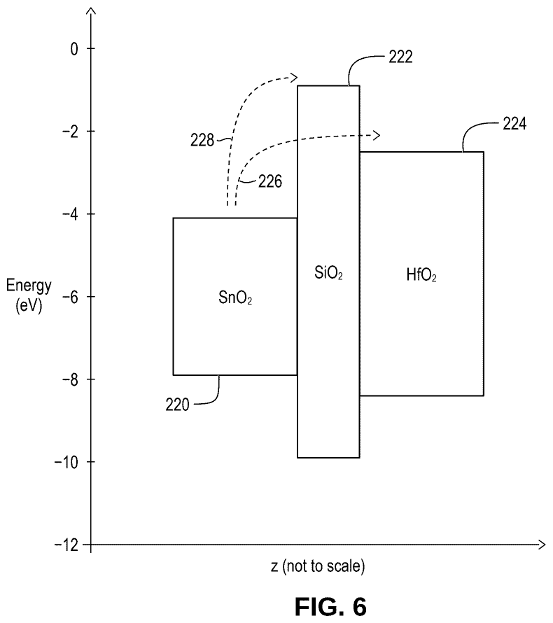

FIG. 6 shows aligned bandgaps (approx. valence band maximum or VBM to approx. conduction band minimum or CBM) of example tin oxide channel material 220, example silicon dioxide interceding material 222, and example hafnium oxide gate dielectric material 224. The plotted values are approximate and not to scale. As can be seen, the interceding material 222 increases the energy needed for an electron to pass from the conduction band of the channel material 220 to the conduction band of the dielectric material 224. Without the interceding material 222, a relatively low quantum of energy 226 is needed for an electron to transfer from the channel material 220 to the dielectric material 224. With the interposed interceding material 222, a higher quantum of energy 228 is needed for an electron to transfer from the channel material 220 to the dielectric material 224.

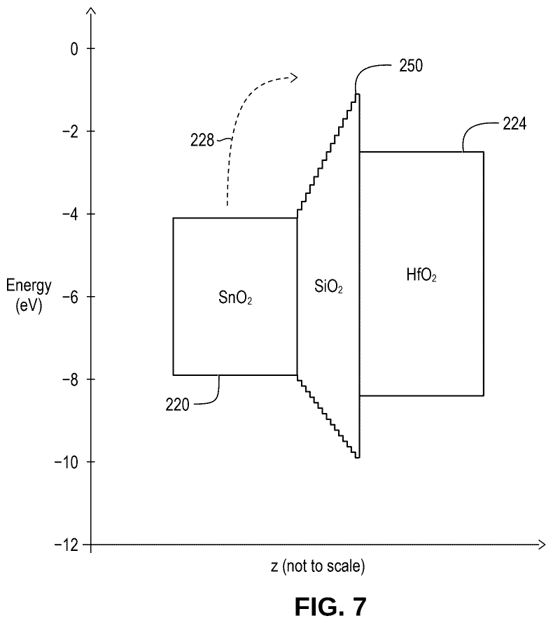

FIG. 7 shows a similar plot in the case of example silicon dioxide interceding material 250 that is graduated from 0 to 100% relative to the tin oxide channel material 220, as discussed with regard to FIG. 4. Such a gradual transition from channel material 220 to interceding material 250 may, despite the appearance of the slope, increase the barrier effect of the interceding material 250 to require a higher quantum of energy 228 due to the wave behavior of electrons. In addition, while the curvature of the transition is shown as linear, it should be understood that this is an approximation, and the actual curvature may be affected by other processes, such as annealing. Further, the curvature of the transition may be tailored for a desired barrier effect.

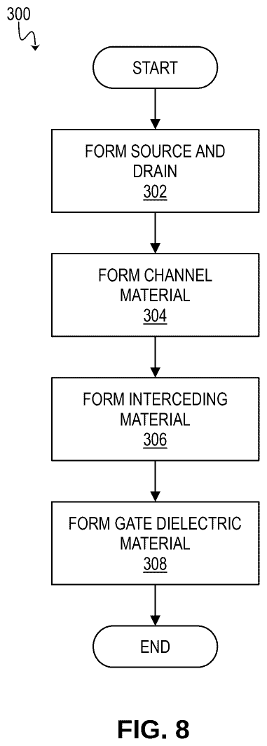

FIG. 8 shows an example method 300 of forming a TFT, such as the TFT 10, with an interceding material between channel and gate dielectric materials. Various process steps have been discussed above these may be included in or omitted from implementations of the method 300 to meet specific implementation requirements.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present invention.

At block 302, a source and spaced-apart drain are formed over a substrate.

At block 304, a body of channel material is formed between the source and the drain. The body of channel material may also extend over parts of the source and drain.

At block 306, interceding material is formed over the body of channel material. Examples of interceding materials are given above. The interceding material may include a combination of two or more materials. The interceding material may be formed as a gradient with respect to the channel material. In addition or alternatively, the composition of the interceding material itself may be graduated. Details of such have been given above.

At block 308, a body of dielectric material is formed over at least a portion of the interceding material. Subsequently, gate material and other components of the TFT may be formed.

Variations of the method 300 are contemplated as useful without departing from the present disclosure. For example, a gate-on-bottom TFT would have a different ordering of blocks, in that the body of dielectric material would be formed before the interceding material and that the channel material would be formed after the interceding material.

In view of the above, interceding material may be provided between channel and gate dielectric materials of a TFT to help retain the desired crystal (or amorphous) structure of the channel and gate dielectric materials, to provide a barrier to undesirable electron (carrier) transfer, and/or to provide a barrier against migration of chemical species, such as oxygen, within the TFT.

Auxiliary verbs “can” and “may” are used interchangeably herein to denote components, features, and/or aspects of the present invention that are capable, configurable, selectable, modifiable, or optional, as would be apparent to one of ordinary skill in the art given the benefit of this disclosure. These terms should not be taken as limiting the present invention, unless otherwise specified.

Spatial prepositions, such as “over”, “under”, “above”, “below”, “up”, “down”, “beside”, etc., are provided for sake of explanation and should not be taken as limiting the present invention to an absolute spatial orientation or arrangement, unless otherwise specified. For example, one of ordinary skill in the art would understand that a first element is above or below a second element depending on the perspective of the observer.

The articles “a”, “an”, “the”, “said”, etc. indicate singular and plural, unless otherwise specified.

The conjunction “or” is used inclusively and should be understood to mean “and/or”, unless otherwise specified.

Sets of elements A, B, C described as A, B, or C; A, B, and C; A, B, and/or C; or A, B, C should be considered open sets from which one or more elements or a combination of one or more elements may be selected, unless otherwise specified. Sets of elements are open, unless specified to be closed, for example, by use of the term “consist”, “consisting”, or similar closed language.

The above clarifications apply to both the specification and claims.

The figures are not to scale, unless otherwise specified.

The above-described examples are intended to be examples of the present invention and alterations and modifications may be effected thereto, by those of ordinary skill in the art, without departing from the scope of the invention which is defined solely by the claims appended hereto.

1. A thin-film transistor comprising:
a substrate;
a source disposed over a portion of the substrate;
a drain disposed over a portion of the substrate;
a body of channel material disposed over at least a portion of the substrate that extends between the source and the drain;
a body of gate material that extends over the body of the channel material;
a body of dielectric material that is disposed between the body of gate material and the body of channel material and that extends over the body of channel material; and
an interceding material disposed between the body of channel material and the body of dielectric material;
wherein the body of channel material includes a metal oxide, the body of channel material being operable to form a carrier channel between the source and the drain when sufficient voltage is applied to the body of gate material; and
wherein the interceding material is operable to reduce or eliminate an influence of a crystal structure of the body of channel material on a structure of the body of dielectric material.

2. The thin-film transistor of claim 1, wherein the interceding material includes one or more of silicon dioxide, silicon oxynitride, and silicon nitride.

3. The thin-film transistor of claim 2, wherein the interceding material is amorphous.

4. The thin-film transistor of claim 1, wherein the interceding material has a graduated composition of two or more of silicon dioxide, silicon oxynitride, and silicon nitride.

5. The thin-film transistor of claim 1, wherein:
the channel material is tin oxide;
the dielectric material is hafnium oxide.

6. The thin-film transistor of claim 5, wherein the tin oxide channel material has a preferred crystallite orientation of Miller index <110>.

7. The thin-film transistor of claim 5, wherein the hafnium oxide dielectric material has a preferred crystallite orientation of Miller index <−111>.

8. The thin-film transistor of claim 5, wherein the hafnium oxide dielectric material has a preferred crystallite orientation of Miller index <020>.

9. The thin-film transistor of claim 5, wherein the hafnium oxide dielectric material has an amorphous structure.

10. The thin-film transistor of claim 1, wherein the interceding material is formed as a discrete layer.

11. The thin-film transistor of claim 1, wherein the interceding material is blended with the channel material.

12. The thin-film transistor of claim 1, wherein the interceding material is graduated according to a gradient with respect to the channel material such that the proportion of interceding material relative to channel material increases with increasing distance from the body of channel material.

13. A method of forming a thin-film transistor comprising:
forming a source over a substrate;
forming a drain over the substrate;
forming a body of channel material between the source and the drain;
forming an interceding material at the body of channel material;
forming a body of dielectric material over at least a portion of the interceding material; and
wherein the interceding material is to reduce or eliminate an influence of a crystal structure of the body of channel material on a structure of the body of dielectric material.

14. The method of claim 13, wherein the interceding material includes one or more of silicon dioxide, silicon oxynitride, and silicon nitride.

15. The method of claim 14, wherein the interceding material is amorphous.

16. The method of claim 13, comprising forming the interceding material with a graduated composition of two or more of silicon dioxide, silicon oxynitride, and silicon nitride.

17. The method of claim 11, wherein:
the channel material is tin oxide;
the dielectric material is hafnium oxide.

18. The method of claim 17, wherein the tin oxide channel material has a preferred crystallite orientation of Miller index <110>.

19. The method of claim 17, wherein the hafnium oxide dielectric material has a preferred crystallite orientation of Miller index <−111>.

20. The method of claim 17, wherein the hafnium oxide dielectric material has a preferred crystallite orientation of Miller index <020>.

21. The method of claim 17, wherein the hafnium oxide dielectric material has an amorphous structure.

22. The method of claim 13, comprising forming the interceding material as a discrete layer on the body of channel material.

23. The method of claim 13, comprising blending the interceding material with the channel material.

24. The method of claim 13, comprising forming the interceding material as graduated according to a gradient such that a proportion of interceding material relative to the channel material increases with increasing distance from the body of channel material.

25. The method of claim 13, comprising forming the interceding material with a proportion with respect to the channel material using thickness modulation of a layer of the interceding material and/or a layer of the channel material.

26. The method of claim 13, comprising forming the interceding material with a proportion with respect to the channel material using frequency modulation of layers of the interceding material and the channel material.

27. The method of claim 13, comprising forming the interceding material with a proportion with respect to the channel material in an atomic layer of the interceding material and the channel material.

28. The method of claim 13, comprising forming the body of channel material, the interceding material, and the body of dielectric material using atomic layer deposition.
